(19) United States
(12) Patent Application Publication
(10) Pub. No.: US 2013/0234280 A1
(43) Pub. Date: Sep. 12, 2013

(54) SHALLOW TRENCH ISOLATION IN DYNAMIC RANDOM ACCESS MEMORY AND MANUFACTURING METHOD THEREOF

(71) Applicants: ARVIND KUMAR, TAOYUAN COUNTY (TW); ERIC LAHAUG, BRISTOW, VA (US); DEVESH KUMAR DATTA, WOODSVALE (SG); KEEN WAH CHOW, MARSILING RISE (SG); CHIA MING YANG, KAOHSIUNG CITY (TW); CHIEN-CHI LEE, TAIPEI CITY (TW); FREDERICK DAVID FISHBURN, MORGAN HILL, CA (US)

(72) Inventors: ARVIND KUMAR, TAOYUAN COUNTY (TW); ERIC LAHAUG, BRISTOW, VA (US); DEVESH KUMAR DATTA, WOODSVALE (SG); KEEN WAH CHOW, MARSILING RISE (SG); CHIA MING YANG, KAOHSIUNG CITY (TW); CHIEN-CHI LEE, TAIPEI CITY (TW); FREDERICK DAVID FISHBURN, MORGAN HILL, CA (US)

(73) Assignee: INOTERA MEMORIES, INC., TAOYUAN COUNTY (TW)

(21) Appl. No.: 13/421,979

(22) Filed: Mar. 16, 2012

(30) Foreign Application Priority Data
Mar. 12, 2012 (TW) 101108354

(51) Int. Cl. H01L 29/06; H01L 21/762

(52) U.S. Cl. 257/506; 438/423; 257/E21.556; 257/E29.02

(57) ABSTRACT

A manufacturing method of STI in DRAM includes the following steps. Step 1 is providing a substrate and step 2 is forming at least one trench in the substrate. Step 3 is doping at least one of side portions and bottom portions of the trench with a dopant. Step 4 is forming an oxidation inside the trench and step 5 is providing a planarization step to remove the oxidation. The stress of the corners of STI is reduced so as to modify the defect of the substrate and improve the DRAM variability in retention time.

### BACKGROUND OF THE INVENTION

1. Field of the Invention

The present invention relates to a shallow trench isolation in DRAM and a manufacturing method thereof. In particular, the present invention relates to a shallow trench isolation in DRAM and a manufacturing method thereof having property of improvement on variability in data retention time.

2. Description of Related Art

Integrated circuits are developed in the trend of high-performance, small-size and low-power consuming; for example, various approaches have been taken to reduce the cell size of dynamic random access memory (DRAM) and improve the capability thereof. Usually, the DRAM cell or memory cell has a transistor, a capacitor and a peripheral circuit. In resent time, DRAM cell density has increased and the number of the DRAM cells on a DRAM chip is expected to exceed several gigabits data. As this DRAM cell density increases on the DRAM chip, it is necessary to reduce the area of each DRAM cell, while improving performance at the same time.

As DRAM cells are scaled to meet a chip size requirement for high storage capability, the retention time requirement is degraded. In other words, the performance and the manufacturing yield of DRAMs are degraded.

Variability in data retention time is a challenge for high quality DRAMs and variability in retention time poses serious reliability and operational problems in DRAMs. The variability in retention time is mainly caused by uncontrolled charge leakage from the DRAM cell. The charge leakage mechanism is resulted from cell side junction leakage, gate induced drain leakage and defect assisted leakage from the channel, and almost all the leakage are caused by various defects in silicon. For example, the unpredictable defects are created during plasma etching steps in DRAM processes and high plasma energy process may create permanent lattice defects in silicon, such as dislocations/slip planes.

On the other hand, shallow trench isolation (STI) is used for creating an isolation between DRAM active area and field and STI is formed by a deep trench etch using high energy plasma which leads to a very defective bottom and sidewalk in silicon. The induced crystal defects and imperfections create stress in STI corners and walls. Moreover, the etched deep trench is filled of dielectric materials which also add in to stress on the silicon lattice. Thus, the compressive stress at STI corners is also believed to be one of the causes for variability in retention time.

The above-mentioned leakage caused by lattice defects in silicon detrimentally impacts retention performance in the DRAM application. Thus, there is a need for DRAM having the reduced stress at STI corners to help in minimizing the variability in DRAM retention time.

### SUMMARY OF THE INVENTION

One object of the instant disclosure is providing a STI structure and a manufacturing method thereof. The present invention may reduce lattice defects in silicon such as dislocations/slip planes, which is resulted from stress near STI. Therefore, the reduced stress at STI corners can certainly help in reducing the variability in DRAM retention time.

The instant disclosure provides a manufacturing method of STI in DRAM, comprising the following steps: step 1 is providing a substrate; step 2 is forming at least one trench in the substrate; step 3 is doping at least one of side portions and bottom portions of the trench with a dopant; step 4 is forming an oxidation inside the trench; and step 5 is providing a planarization step to remove the oxidation.

The method further includes a step of heating the substrate and the dopant in the step of doping at least one of side portions and bottom portions of the trench with a dopant or after the step of doping at least one of side portions and bottom portions of the trench with a dopant.

The instant disclosure provides a STI in DRAM including a substrate; at least one trench formed on a surface of the substrate and an oxidation filled in the trench and covering the dopant. The trench has a dopant in at least one of side portions and bottom portions thereof.

Preferably, the dopant is boron (B), carbon (C) or another element of group IV-A. The dopant dose is smaller than 1.5E14 ions/cm². The doping energy of the dopant is smaller than 25 keV.

Moreover, the substrate is substantially comprises polysilicon and the oxidation substantially comprises tetraethyl orthosilicate (TEOS), phosphor-silicate glass (PSG) or un-doped silicon glass.

By applying the STI structure, the stress at STI corners are reduced; thus, the defects distribution, such as dislocations/slip planes near STI is modified. STI can be used for creating an isolation between DRAM active area and field, and the reduced stress at STI corners can certainly help in reducing the variability in DRAM retention time.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 shows a flow chart of the manufacturing method of shallow trench isolation of the instant disclosure.

FIG. 2 shows a formed structure of step “X1” of the manufacturing method of the instant disclosure.

FIG. 3 shows a formed structure of step “X2” of the manufacturing method of the instant disclosure.

FIG. 4 shows a formed structure of step “X3” of the manufacturing method of the instant disclosure.

FIG. 5 shows a formed structure of step “X5” of the manufacturing method of the instant disclosure.

FIG. 6 shows a formed structure of step “X6” of the manufacturing method of the instant disclosure.

### DETAILED DESCRIPTION OF THE PREFERRED EMBODIMENTS

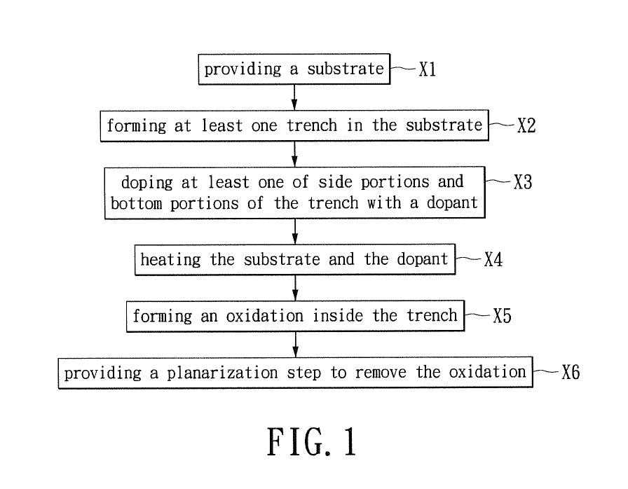

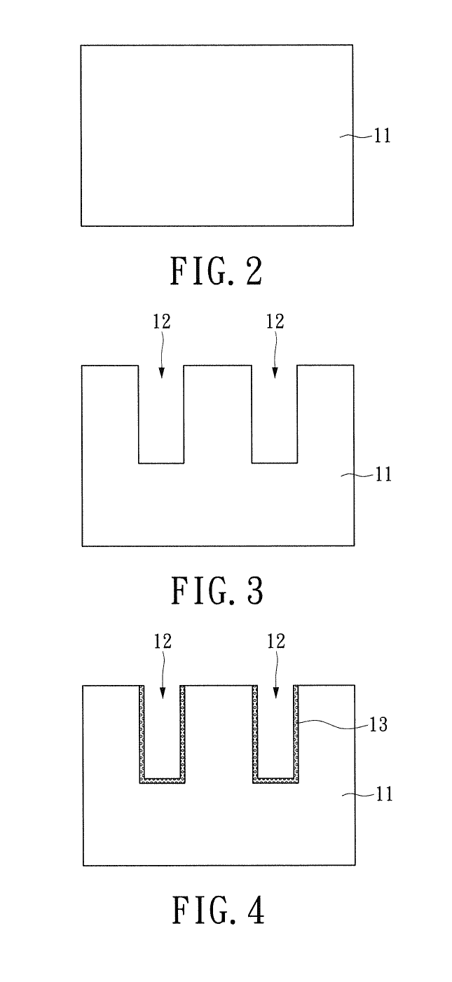

Please refer to FIG. 1 and FIGS. 2 thru 6; a flow chart of the present manufacturing method of shallow trench isolation (STI) 10 in dynamic random access memory (DRAM) is shown in FIG. 1 and the formed structures of each step of the method are shown in FIGS. 2 to 6. The present manufacturing method of shallow trench isolation (STI) 10 in DRAM has the following steps. As shown in FIG. 2, the step “X1” is providing a substrate 11, and preferably, the substrate 11 is a single-crystal silicon substrate or polysilicon substrate. Then, the step “X2” is forming at least one trench 12 in the substrate 11 as shown in FIG. 3. In the exemplary embodiment, lithography and etch methods may be used to forming the trench 12 on a surface of the substrate 11. By etching the substrate 11, the trench 12 can be efficiently and low-costly formed on the substrate 11.

Please refer to FIG. 4; the step “X3” is doping at least one of side portions and bottom portions of the trench 12 with a dopant 13. Preferably, the dopant 13 can be boron (B), or element of group IV-A, such as carbon (C). In an exemplary, the dopant dose is smaller than 1.5E14 ions/cm², and the doping energy is smaller than 25 keV. As shown in TABLE 1, the failed refresh bit count and the VRT (variability in data retention time) count of Embodiments 1-4 are improved by doping carbon in the bottom or side wall of the trench 12. On the other hand, carbon dopants 13 are preferably to be with in ˜10 nm of STI bottom for stress modification. For doping the dopant 13 in the bottom portions of the trench 12, a method of ion implantation may be used. The ion implantation is performed so that the concentration distribution profile is precisely controlled and the advantages of high reproduction and low-temperature working are achieved. On the other hand, for doping the dopant 13 in the side portions of the trench 12, vapor of the dopant 13 is doped into the substrate 11 by diffusing. In an alternatively method, an oxide layer containing the dopant 13 is formed on the side walls of the trench 12 and then the ions or atoms of the dopant 13 is driven into the substrate 11 in a high temperature environment. Furthermore, the present method may have a step “X4” for heating the substrate 11 and the dopant 13 for obtaining uniform concentration distribution profile. The heating step may be performed in the step “X3” (i.e., simultaneously performed in the doping step) or after the step “X3”. Therefore, the high temperature step provides the opportunity for dopant 13 to diffuse to more-lightly doped region. Thus far, diffusion doping processes are capable of achieving uniform dopant concentration on the side portions or the bottom portions of the trench 12.

TABLE 1

| | | | Failed refresh | VRT |
|---|---|---|---|---|
| | | | bit count | count |
| | Field implant | C-implant | (AU) | (AU) |
| Tset 1 | 3E12/10 keV | None | 191 | 6.8 |
| Embodiment1 | 3E12/10 keV | 15E14/15 keV | 175 | 6.5 |
| Embodiment2 | 3E12/10 keV | 15E14/25 keV | 186 | 5.7 |
| Embodiment3 | 6E12/10 keV | 15E14/15 keV | 176 | 4.7 |
| Embodiment4 | 6E12/10 keV | 15E14/25 keV | 173 | 6.2 |

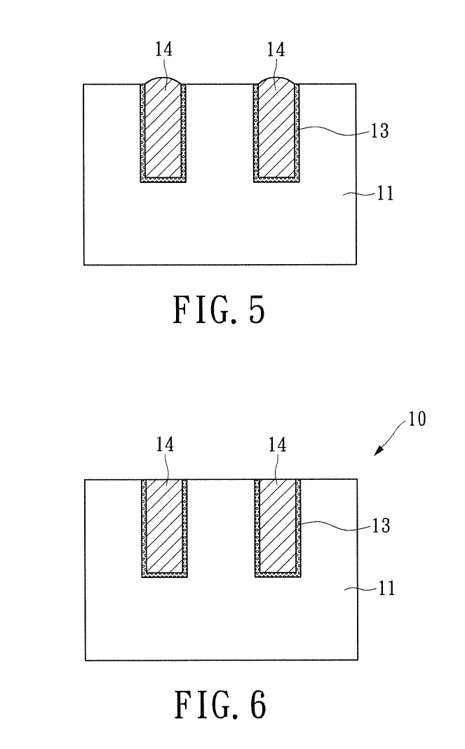

Please refer to FIG. 5; step “X5” is forming an oxidation 14 inside the trench 12 after the doping step. In the exemplary embodiment, the oxidation 14, which is filled into the trench 12 by physical vapor deposition (PVD) or chemical vapor deposition (CVD), can be tetraethyl orthosilicate (TEOS), phosphor-silicate glass (PSG) or un-doped silicon glass (USG). By using the above-mentioned deposition methods, the advantage of precise control of the film thickness, the film quality and the composition of the oxidation 14 may be achieved.

Please refer to FIG. 6; step “X6” is providing a planarization step to remove the oxidation 14. In the exemplary, the oxidation 14 is removed by a chemical mechanical polish (CMP) to form a planarized surface on the substrate 11. Accordingly, the shallow trench isolation (STI) 10 is manufactured. The substrate 11 has one or more trenches 12 formed thereon and each trench 12 has a dopant 13 on the side portions and the bottom portions thereof. In addition, an oxidation 14 is filled inside the trench 12 to cover the dopant 13.

According to the experimental results, dopant atoms at STI bottom or STI corners modify the defects distribution near STI which is resulted from reduced stress at STI bottom or STI corners. The present STI can be applied as an isolation structure between electrodes of DRAM and a significant reduction in variability in data retention time (>30%) can be achieved by only 1 additional implant process step, which is very important for DRAM quality and reliability.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A manufacturing method of a shallow trench isolation in DRAM, comprising the following steps:
providing a substrate;
forming at least one trench in the substrate;
doping at least one of side portions and bottom portions of the trench with a dopant;
forming an oxidation inside the trench; and
providing a planarization step to remove the oxidation.

2. The manufacturing method as claimed in claim 1, further comprising a step of heating the substrate and the dopant in the step of doping at least one of side portions and bottom portions of the trench with a dopant or after the step of doping at least one of side portions and bottom portions of the trench with a dopant.

3. The manufacturing method as claimed in claim 1, wherein the dopant is boron (B), carbon (C) or another element of group IV-A.

4. The manufacturing method as claimed in claim 1, wherein the dopant dose is smaller than 1.5E14 ions/cm².

5. The manufacturing method as claimed in claim 1, wherein a doping energy is smaller than 25 keV in the step of doping at least one of side portions and bottom portions of the trench with a dopant.

6. A shallow trench isolation in DRAM, comprising:
a substrate;
at least one trench formed on a surface of the substrate, the trench has a dopant in at least one of side portions and bottom portions thereof; and
an oxidation filled in the trench and covering the dopant.

7. The shallow trench isolation as claimed in claim 6, wherein the dopant is boron (B), carbon (C) or another element of group IV-A.

8. The shallow trench isolation as claimed in claim 6, wherein the dopant dose is smaller than 1.5E14 ions/cm².

9. The shallow trench isolation as claimed in claim 6, wherein a doping energy of the dopant is smaller than 25 keV.

10. The shallow trench isolation as claimed in claim 6, wherein the substrate is substantially comprises polysilicon, and the oxidation substantially comprises tetraethyl orthosilicate (TEOS), phosphor-silicate glass (PSG) or un-doped silicon glass.
